(19) United States
(12) Patent Application Publication
(10) Pub. No.: US 2024/0140873 A1
(43) Pub. Date: May 2, 2024

(54) SINTERED BODY AND METHOD OF MANUFACTURING SINTERED BODY

(71) Applicant: SK enpulse Co., Ltd., Pyeongtaek-si (KR)

(72) Inventors: Kyung yeol MIN, Seoul (KR); Yongsoo CHOI, Seoul (KR); SungSic HWANG, Seoul (KR); Na Hyun NAM, Seoul (KR); Kyung In KIM, Seoul (KR); Jung Kun KANG, Seoul (KR); Woo Jin LEE, Seoul (KR)

(73) Assignee: SK enpulse Co., Ltd., Pyeongtaek-si (KR)

(21) Appl. No.: 18/468,959

(22) Filed: Sep. 18, 2023

(30) Foreign Application Priority Data
Oct. 27, 2022 (KR) 10-2022-0140205

(51) Int. Cl. C04B 35/14; C04B 35/532; C04B 35/626

(52) U.S. Cl. CPC C04B 35/14; C04B 35/532; C04B 35/62655; C04B 2235/3418

(57) ABSTRACT

The sintered body including silicon oxide and carbon, wherein the sintered body has a D band peak at a wave number of 1,311 cm⁻¹ to 1,371 cm⁻¹ and a G band peak at a wave number of 1,572 cm⁻¹ to 1,632 cm⁻¹ in a Raman spectrum, and wherein the D band peak or the G band peak have a higher intensity than a fifth peak present at a wave number of 1,027 cm⁻¹ to 1,087 cm⁻¹ in the Raman spectrum, is disclosed.

### CROSS-REFERENCE TO RELATED APPLICATION

This application claims the benefit under 35 USC § 119(a) of Korean Patent Application No. 10-2022-0140205, filed on Oct. 27, 2022, the disclosure of which is incorporated herein by reference in its entirety.

### BACKGROUND

### 1. Field of the Invention

The present disclosure relates to a sintered body including silicon oxide and a small amount of carbon, and a method of manufacturing the sintered body.

### 2. Discussion of Related Art

A plasma treatment method used as one of dry etching methods in a process of manufacturing a semiconductor is a method of etching a target with a fluorine-based gas, and the like. In recent years, a design for manufacture of electronic components is becoming increasingly elaborate. In particular, plasma etching requires higher dimensional accuracy, and uses significantly higher power.

Such a plasma processing apparatus may include a built-in quartz glass part, which is affected by plasma. Quartz glass may prevent contamination of an etching target due to relatively low generation of impurities. Various studies have been conducted to extend the lifespan of these quartz glass-related parts in the plasma processing apparatus. Accordingly, there is a need for considering ways to improve the lifespan and durability of parts by improving the limitations of quartz glass.

The above-described background is technical information that the inventor possessed or acquired for conceiving embodiments of the present disclosure, and cannot necessarily be a known technology disclosed to a general public prior to the filing of the present disclosure.

### SUMMARY OF THE INVENTION

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, the sintered body includes silicon oxide and carbon, wherein the sintered body may have a D band peak at a wave number of 1,311 cm⁻¹ to 1,371 cm⁻¹ and a G band peak at a wave number of 1,572 cm⁻¹ to 1,632 cm⁻¹ in a Raman spectrum, and wherein the D band peak or the G band peak may have a higher intensity than a fifth peak present at a wave number of 1,027 cm⁻¹ to 1,087 cm⁻¹ in the Raman spectrum.

The D band peak or the G band peak may have an intensity 1.5 times or more and 5 times or less higher than the fifth peak.

The D band peak or the G band peak may have a higher intensity than a fourth peak present at a wave number of 762 cm⁻¹ to 822 cm⁻¹.

An average intensity at a wave number of 1,212 cm⁻¹ to 1,262 cm⁻¹ in the Raman spectrum may be higher than the intensity of the fifth peak.

An intensity ratio I_{d}/I_{g} of the D band peak and the G band peak may be greater than or equal to 0.9 and less than or equal to 1.5.

The sintered body may have a compressive strength of 380 MPa or more and 580 MPa or less.

A content of the carbon may be greater than or equal to 0.01% by weight and less than or equal to 1.5% by weight based on a total weight of the sintered body.

A content of silicon may be greater than or equal to 40% by weight and less than or equal to 49% by weight based on a total weight of the sintered body and a content of oxygen may be greater than or equal to 47% by weight and less than or equal to 56% by weight based on a total weight of the sintered body.

The sintered body may include a metal impurity selected from the group consisting of magnesium, potassium, calcium, chromium, iron, nickel, and barium.

A content of the magnesium may be greater than or equal to 100 ppb and less than or equal to 2,500 ppb based on a total weight of the sintered body; a content of the potassium may be greater than or equal to 500 ppb and less than or equal to 2,500 ppb based on the total weight of the sintered body; a content of the calcium may be greater than or equal to 1,000 ppb and less than or equal to 1,200 ppb based on the total weight of the sintered body; a content of the chromium may be greater than or equal to 100 ppb and less than or equal to 1,000 ppb based on the total weight of the sintered body; a content of the iron may be greater than or equal to 800 ppb and less than or equal to 5000 ppb based on the total weight of the sintered body; a content of the nickel may be greater than or equal to 50 ppb and less than or equal to 800 ppb based on the total weight of the sintered body; and a content of the barium may be greater than or equal to 100 ppb and less than or equal to 2000 ppb based on the total weight of the sintered body.

A thickness decrease rate of the sintered body after etching under the following plasma etching conditions in a chamber may be less than or equal to 1.38% compared to a thickness decrease rate of the sintered body before etching: a chamber pressure of 100 mTorr, a plasma power of 800 W, an exposure time of 300 minutes, a CF₄ flow rate of 50 sccm, an Ar flow rate of 100 sccm, and an O₂ flow rate of 20 sccm.

An L* value of a CIE L*a*b* color space according to ASTM E1164 of the sintered body may be greater than or equal to 0 and less than or equal to 85.

A light transmittance of the sintered body at a wavelength of 550 nm may be 0.5% or more and 30% or less.

In another general aspect, the plasma etching-resistant part includes the sintered body as a coating layer on a surface of the plasma etching-resistant part.

A thickness of the coating layer may be greater than or equal to 50 mm and less than or equal to 1,000 mm.

The plasma etching-resistant part may be a focus ring in a plasma etching device.

In another general aspect, the method of manufacturing a sintered body includes: forming a raw material composition in a form of granules; and molding, carbonizing and sintering the raw material composition, wherein the raw material composition may include silicon oxide, a carbonizing resin, and an auxiliary additive.

A content of the carbonizing resin may be greater than or equal to 0.1% by weight and less than or equal to 8% by weight based on a total weight of the raw material composition.

The forming of the raw material composition may be performed by spray drying the raw material composition.

The auxiliary additive may include one selected from the group consisting of a polyacrylic acid-based resin, a polycarboxylic acid-based resin, a C₁₀-C₄₀ alkane, a fatty acid amide, and a combination thereof.

Other features and aspects will be apparent from the following detailed description, the drawings, and the claims.

### BRIEF DESCRIPTION OF THE DRAWINGS

The above and other objects, features and advantages of the present disclosure will become more apparent to those of ordinary skill in the art by describing in detail embodiments thereof with reference to the accompanying drawings.

FIG. 1 is a Raman spectrum graph showing the intensities of Example 1 (E1) and Comparative Examples 1 and 2 (CE1 and CE2) according to wave number, as measured by Raman spectroscopy performed in the Experimental Example.

FIG. 2 is an image of samples of Example 1 (E1) and Comparative Examples 1 and 2 (CE1 and CE2).

FIG. 3 is a graph showing the F1s Scan results obtained by XPS analysis of Example 1 (E1) and Comparative Examples 1 and 2 (CE1 and CE2) performed in the Experimental Example.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION OF EXEMPLARY EMBODIMENTS

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

Throughout the specification, unless otherwise specified, when an element is referred to as “including” another element, it will be understood to mean the inclusion of stated elements but not the exclusion of any other elements.

Throughout the specification, when an element is referred to as being “connected” or “coupled” to another element, it can be directly connected or coupled to the other element or intervening elements may be present.

In the present specification, it will be understood that when “B” is referred to as being on “A,” “B” can be directly on “A” or other component(s) may be interposed therebetween. That is, the location of “B” is not construed as being limited to direct contact of “B” with the surface of “A.”

Throughout the specification, the term “combination of” included in Markush type description refers to a mixture or combination of one or more components selected from a group consisting of components described in the Markush form and thereby means including one or more components selected from the Markush group.

In the present specification, the description of “A and/or B” means “A, or B, or A and B.”

In the present specification, the terms such as “first,” “second” or “A,” “B” are used to distinguish the same terms from each other, unless otherwise specified.

In the present specification, the singular forms “a” “an” and “the” are intended to include the plural forms as well, unless the context clearly specifies otherwise.

It is an object of the present disclosure to provide a quartz glass-based sintered body exhibiting excellent plasma resistance properties, and a method of manufacturing the same.

Sintered Body

To achieve the above objects, the sintered body according to the present disclosure includes silicon oxide and carbon, wherein the sintered body may have a D band peak at a wave number of 1,311 cm⁻¹ to 1,371 cm⁻¹ and a G band peak at a wave number of 1,572 cm⁻¹ to 1,632 cm⁻¹ in the Raman spectrum obtained by Raman spectroscopy, and wherein the D band peak or the G band peak may have a higher intensity than a fifth peak present at a wave number of 1,027 cm⁻¹ to 1,087 cm⁻¹ in the Raman spectrum.

Quartz glass is glass including silicon oxide (SiO₂), and may be referred to as a material that is important in a semiconductor process due to its low thermal expansion coefficient, chemical durability, and the like.

According to the present disclosure, a quartz glass sintered body, in which a certain amount of carbon is included as a type of defect in a Si—O amorphous network structure, is provided. The sintered body of the present disclosure may have a Raman spectrum, chromaticity, transmittance, reflectance, plasma etching resistance, compressive strength, and the like different from those of conventional quartz glass.

The Raman spectrum of the sintered body may be obtained using a Raman spectrometer DxR2 (commercially available from Thermo Scientific Inc.), and the specific conditions will be described in the Experimental Example below.

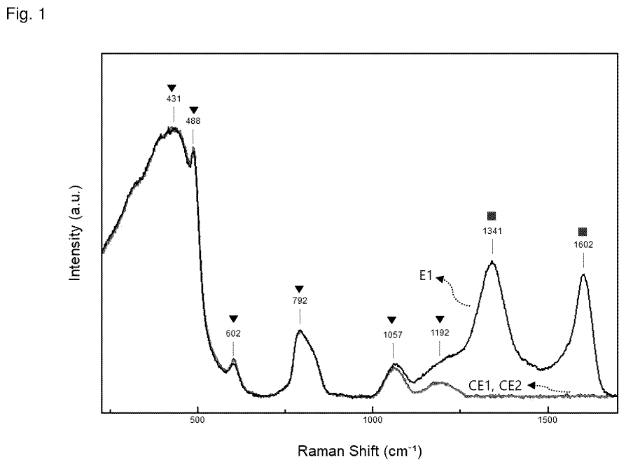

The Raman spectrum of the sintered body (E1) according to the present disclosure was compared with the Raman spectra of conventional quartz glasses (CE1 and CE2), as shown in FIG. 1. Referring to the results, it can be seen that the Raman spectra of the conventional quartz glasses and the sintered body of the present disclosure commonly have Si—O-related peaks.

Specifically, a first peak is present at a wave number of 421 cm⁻¹ to 441 cm⁻¹ and related to the vibration of SiO₂, a second peak is present at a wave number of 478 cm⁻¹ to 498 cm⁻¹ and related to the breathing vibration of oxygen atoms in 4-membered and 3-membered rings, a third peak is present at a wave number of 582 cm⁻¹ to 622 cm⁻¹ and related to the breathing vibration of oxygen atoms in a 3-membered ring, a fourth peak is present at a wave number of 762 cm⁻¹ to 822 cm⁻¹ and related to the bending of a Si—O—Si bridge, and a fifth peak is present at a wave number of 1,027 cm⁻¹ to 1,087 cm⁻¹ and related to Si—O stretching.

It can be seen that the sintered body of the present disclosure has a pattern different from the intensity of the fifth peak at a wave number of 1,057 cm⁻¹ or more, compared to conventional synthetic quartz glass. Also, it can be seen that the conventional quartz glass has a sixth peak close to a wave number of 1,192 cm⁻¹ in the Raman spectrum, but according to the present disclosure, no clear peaks are observed around this region due to an effect of defective carbon. It can be seen that the sintered body of the present disclosure has a structural difference capable of improving plasma etching resistance.

In the Raman spectrum of the sintered body, the D band peak or the G band peak may have a higher intensity than the fifth peak present at a wave number of 1,027 cm⁻¹ to 1,087 cm⁻¹ in the Raman spectrum. The D band peak or the G band peak may have an intensity 1.5 times or more higher than the fifth peak, an intensity 2 times or more higher than the fifth peak, or an intensity 5 times or less higher than the fifth peak. The sintered body having such a Raman spectrum may exhibit further improved plasma etching resistance due to defective carbon.

In the Raman spectrum of the sintered body, the D band peak or the G band peak may have a higher intensity than the fourth peak present at a wave number of 762 cm⁻¹ to 822 cm⁻¹. The D band peak or the G band peak may have an intensity 1.2 times or more higher than the fourth peak, an intensity 1.5 times or more higher than the fourth peak, or an intensity 4 times or less higher than the fourth peak. The sintered body having such a Raman spectrum may exhibit further improved plasma etching resistance due to defective carbon.

In the Raman spectrum of the sintered body, an intensity ratio I_{d}/I_{g} of the D band peak and the G band peak may be 0.9 or more and 1.5 or less. In the sintered body having such a Raman spectrum, defective carbon may be positioned in the Si—O network structure in a quasi-stable manner.

In the Raman spectrum of the sintered body, the intensity of the fifth peak may be higher than the intensity of the fifth peak of the synthetic quartz glass and conventional quartz glass (NIFS-S product commercially available from NIKON Corp., N product commercially available from TOSOH Corp.). In the Raman spectrum of the sintered body, a value obtained by integrating the intensity at a wave number of 1,200 cm⁻¹ to 1,700 cm⁻¹ may be higher than a value obtained by integrating the intensity at a wave number of 600 cm⁻¹ to 1,100 cm⁻¹. The sintered body having such a Raman spectrum may exhibit further improved plasma etching resistance due to its unique structure.

In the Raman spectrum of the sintered body, the average intensity at a wave number of 1,212 cm⁻¹ to 1,262 cm⁻¹ may be higher than the intensity of the fifth peak present at a wave number of 1,027 cm⁻¹ to 1,087 cm⁻¹. The sintered body having such a Raman spectrum may exhibit further improved plasma etching resistance due to its unique structure.

The sintered body may have an amorphous structure, in which there is no substantial long-range order and there is some short-range order.

In the sintered body, carbon on the surface of the sintered body may partially react with an etching gas (such as CF₄, and the like) to form a stable polymer layer, which results in further improved plasma etching resistance.

The sintered body may have a compressive strength of 380 MPa or more and 580 MPa or less, or a compressive strength of 400 MPa or more and 550 MPa or less. The sintered body having such compressive strength may be stably positioned in a plasma etching device.

The carbon content of the sintered body may be greater than or equal to 0.01% by weight and less than or equal to 1.5% by weight, greater than or equal to 0.2% by weight and less than or equal to 1.3% by weight, or greater than or equal to 0.3% by weight and less than or equal to 1% by weight, based on the total weight of the sintered body. When the sintered body has such a carbon content, defective carbon may be properly distributed in a structure of amorphous quartz glass, and plasma corrosion resistance may be ensured.

The sintered body may include impurities other than the silicon oxide and carbon.

The silicon oxide of the sintered body may be adjacent to the silicon oxide component (SiO₂) of the raw material.

The silicon content of the sintered body may be greater than or equal to 40% by weight and less than or equal to 49% by weight based on the total weight of the sintered body.

The oxygen content of the sintered body may be greater than or equal to 47% by weight and less than or equal to 56% by weight based on the total weight of the sintered body.

In the sintered body, a thickness decrease rate after etching under the plasma etching conditions in a chamber may be less than or equal to 1.38%, and less than or equal to 1.35%, compared to that before etching. The thickness decrease rate may be calculated as follows:

Thickness decrease rate (%)={(Thickness before etching−Thickness after etching)/Thickness after etching}×100% [Equation 1]

The plasma etching conditions may be as follows: a chamber pressure of 100 mTorr, a plasma power of 800 W, an exposure time of 300 minutes, a CF₄ flow rate of 50 sccm, an Ar flow rate of 100 sccm, and an O₂ flow rate of 20 sccm.

When the sintered body has such a thickness decrease rate (i.e., an etching rate), the sintered body may exhibit further improved plasma etching resistance compared to the conventional quartz glass.

In the sintered body, a weight decrease rate after etching under the plasma etching conditions as described above may be less than or equal to 1.4%, or less than or equal to 1.38%, compared to that before etching. The weight decrease rate may be calculated as follows:

Weight decrease rate (%)={(Weight before etching−Weight after etching)/Weight after etching}×100% [Equation 2]

When the sintered body has such a weight decrease rate, the sintered body may exhibit further improved plasma etching resistance compared to the conventional quartz glass.

In the sintered body, the content of fluorine produced after etching under the plasma etching conditions as described above may be lower than that of synthetic quartz glass.

In the sintered body, the amount of carbon reduced after etching under the plasma etching conditions as described above may be lower than that of synthetic quartz glass.

The sintered body may have a specific resistance at 25° C. of 4.1×10¹⁵ Ωcm or more, or a specific resistance at 25° C. of 4.4×10¹⁵ Ωcm or more. The sintered body may have a specific resistance at 25° C. of 6.0×10¹⁵ Ωcm or less, or a specific resistance at 25° C. of 5.8×10¹⁵ Ωcm or less.

In the sintered body, an L* value of a CIE L*a*b* color space according to ASTM E1164 may be greater than or equal to 0, greater than or equal to 10, or greater than or equal to 15. The L* value may be less than or equal to 85, less than or equal to 60, or less than or equal to 35.

In the sintered body, an a* value of the CIE L*a*b* color space according to ASTM E1164 may be greater than or equal to 1, or greater than or equal to 2. The a* value may be less than or equal to 8, or less than or equal to 5.

In the sintered body, a b* value of the CIE L*a*b* color space according to ASTM E1164 may be greater than or equal to 2, or greater than or equal to 5. The b* value may be less than or equal to 20, or less than or equal to 15.

Such an L*, a*, b* value range of the sintered body appears to result from an effect of defective carbon. In particular, there is a clear difference in the L* value compared to the conventional quartz glass, and the sintered body may appear darker or blacker. The sintered body having such an L*, a*, b* value range may be expected to exhibit further improved plasma corrosion resistance.

The values of the CIE L*a*b* color space of the sintered body may be measured using the method as described in the following Experimental Example.

The sintered body may have a light reflectance at a wavelength of 550 nm of 1% or more, or a light reflectance at a wavelength of 550 nm of 2% or more. The reflectance may be less than or equal to 8%, or less than or equal to 6.5%.

The sintered body may have a light transmittance at a wavelength of 550 nm of 0.5% or more, or a light transmittance at a wavelength of 550 nm of 1% or more. The transmittance may be less than or equal to 30%, or less than or equal to 10%.

Such reflectance and transmittance of the sintered body appears to result from an effect of defective carbon. In particular, there is a clear difference in light transmittance compared to the conventional quartz glass, and the transmittance is much lower. The sintered body having such optical properties may be expected to exhibit further improved plasma corrosion resistance.

The optical properties (such as reflectance, transmittance, and the like) of the sintered body may be determined using the method as described in the following Experimental Example.

The purity of the sintered body may be greater than or equal to 99% by weight or greater than or equal to 99.99% by weight, based on the content of carbon, silicon, and oxygen. The purity may be less than or equal to 99.9999% by weight.

In addition to carbon, the sintered body may include a small amount of metal impurities such as magnesium, potassium, calcium, chromium, iron, nickel, barium, and the like.

The magnesium content of the sintered body may be greater than or equal to 100 ppb and less than or equal to 2,500 ppb based on the total weight of the sintered body.

The potassium content of the sintered body may be greater than or equal to 500 ppb and less than or equal to 2,500 ppb based on the total weight of the sintered body.

The calcium content of the sintered body may be greater than or equal to 1,000 ppb and less than or equal to 1,200 ppb based on the total weight of the sintered body.

The chromium content of the sintered body may be greater than or equal to 100 ppb and less than or equal to 1,000 ppb based on the total weight of the sintered body.

The iron content of the sintered body may be greater than or equal to 800 ppb and less than or equal to 5000 ppb based on the total weight of the sintered body.

The nickel content of the sintered body may be greater than or equal to 50 ppb and less than or equal to 800 ppb based on the total weight of the sintered body.

The barium content of the sintered body may be greater than or equal to 100 ppb and less than or equal to 2000 ppb based on the total weight of the sintered body.

The sintered body may be expected to exhibit good durability because sintered body may be in harmony with these certain metal impurities.

Plasma Etching-Resistant Part

To achieve the above objects, the plasma etching-resistant part according to the present disclosure may include the sintered body. As an example, the sintered body may be included throughout the plasma etching-resistant part, and may also be included as a coating layer having a predetermined thickness on a surface of the plasma etching-resistant part. The thickness of the coating layer may be adjusted in consideration of a degree of plasma etching, and may be greater than or equal to 50 mm and less than or equal to 1,000 mm.

For example, the plasma etching-resistant part may be a focus ring and may correspond to other parts affected by plasma etching in plasma etching devices.

Method of Manufacturing Sintered Body

To achieve the above objects, the method of manufacturing a sintered body according to the present disclosure includes: a granulation step of forming a raw material composition in the form of granules; and a sintering step of molding, carbonizing and sintering the raw material composition in the form of granules, wherein the raw material composition includes silicon oxide, a carbonizing resin, and an auxiliary additive.

The granulation step is a step of forming a raw material composition slurry, which includes silicon oxide, a carbonizing resin, an auxiliary additive, a solvent, and the like, in the form of granules having a predetermined particle size. Through the granulation step, sinterability in the next step may be improved, and the raw material components may be distributed more homogenously.

The granulation step may be performed by spray drying the raw material composition. For example, the raw material composition slurry including a solvent may be atomized through a spray nozzle, gas-liquid mixing may be performed, and the solvent may be evaporated. Accordingly, dried granules may be formed.

The particle size of the raw material granules obtained in the granulation step may be greater than or equal to 5 μm and less than or equal to 95 μm.

The silicon oxide (SiO₂) of the raw material composition may be in the form of powder.

The carbonizing resin of the raw material composition may include a polyvinyl alcohol (PVA)-based resin, a phenol-based resin, polyvinyl butyral (PVB), and the like. As one example, the carbonizing resin may include a polyvinyl alcohol-based resin.

The auxiliary additive of the raw material composition may include a polyacrylic acid-based resin, a polycarboxylic acid-based resin, a C₁₀-C₄₀ alkane (paraffin), a fatty acid amide, and the like. The auxiliary additive may serve as a binder, a dispersant, and the like.

The solvent of the raw material composition may include an alcohol-based solvent, water, and the like.

The content of the carbonizing polymer resin may be greater than or equal to 0.1% by weight and less than or equal to 8% by weight, or greater than or equal to 0.3% by weight and less than or equal to 6% by weight, based on the total weight of the raw material composition. When the carbonizing polymer resin is present at this content, defective carbon may be properly distributed in the structure of amorphous quartz glass of the sintered body manufactured through subsequent processes, which results in improved plasma corrosion resistance.

The content of the auxiliary additive may be greater than or equal to 1% by weight and less than or equal to 8% by weight, or greater than or equal to 2% by weight and less than or equal to 6% by weight, based on the total weight of the raw material composition.

The molding in the sintering step may be performed by injecting the raw material composition in the form of granules into a mold having the shape of a desired part.

The carbonization in the sintering step may be performed by thermal treatment at a temperature of 700° C. or more and 1,100° C. or less.

The sintering in the sintering step may be performed by thermal treatment at a temperature of 1,100° C. or more and 1,300° C. or less for 1 hour or more and 10 hours or less.

The sintered body obtained through the sintering in the sintering step may have characteristics as described above.

Hereinafter, the present disclosure will be described in further detail with reference to the following Examples. However, it should be understood that the following Examples are provided to help the understanding of the present disclosure and the scope of the present disclosure is not limited thereto.

### Example 1: Manufacture of Quartz Glass Sintered Body Including Defective Carbon

A raw material composition, which was obtained by mixing 95% by weight of silicon oxide powder (commercially available from Sukgyung AT Co., Ltd.), 1% by weight of a blend of PVA 205 polyvinyl alcohol resin and PVA 217 polyvinyl alcohol resin (PVA205:PVA217 mixed at a weight ratio of 19.6:80.4; commercially available from Kuraray Co., Ltd.) as a carbonizing resin, 4% by weight of a material including Celuna D-305, Celuna P-222, and Hymicron L-271, HS551 as auxiliary additives, and the balance of a solvent based on the total weight, was prepared, and spray-dried using a spray drying device to form granules having a particle size of approximately 40 to 60 μm. These granules were injected into a focus ring mold, and sintered at a temperature of 1,260° C. for 6 hours to manufacture a sintered body.

### Comparative Example 1: Synthesized Quartz Glass

Quartz glass NIFS-S with a purity of 99.9% (commercially available from NIKON Corp.) was prepared.

### Comparative Example 2: Quartz Glass Prepared by Melting Method

Quartz glass N with a purity of 99.9% (commercially available from TOSOH Corp.) was prepared.

Experimental Example: Raman Analysis

The sintered body of Example 1 and the quartz glasses of Comparative Examples 1 and 2 were subjected to Raman spectroscopy under the following measurement conditions using a Raman spectrometer LabRam Aramis (commercially available from Horiba Jobin Yvon Gmbh). The Raman spectra are shown in FIG. 1.

Excitation wavelength: 514 nm, Power: 5 mW, Resolution: 1.5 cm⁻¹, Scan range: 1×1 μm, and Measurement time: 300 seconds

Referring to FIG. 1, it can be seen that all the sintered body of Example 1(E1) and the quartz glasses of Comparative Examples 1 and 2 (CE1 and CE2) had some common peaks (431, 488, 602, 792, and 1,057 cm⁻¹) related to amorphous SiO₂, but there are differences at a wave number of greater than 1,057 cm⁻¹. In the case of Example 1, the carbon-related D and G band peaks appeared at wave numbers of approximately 1,341 cm⁻¹ and 1,602 cm⁻¹, respectively. In the case of Comparative Examples, such peaks did not appear even when the sintered body included a small amount of carbon.

### Experimental Example: Measurement of Chromaticity, Transmittance, and Reflectance

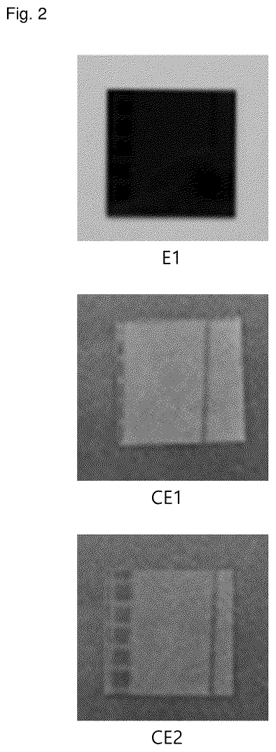

The chromaticity and reflectance of the sintered body of Example 1 and the quartz glasses of Comparative Examples 1 and 2 were measured under the following conditions using CM-5 equipment (commercially available from KONICA MINOLTA Inc.) according to ASTM E1164, and images of the samples were photographed. The results are shown in FIG. 2 and Table 1.

Power source: Xenon lamp (D65); Viewing angle: 10°; Wavelength spacing: 10 nm; and Wavelength range: 360 to 740 nm

Also, the transmittances of the sintered body of Example 1 and the quartz glasses of Comparative Examples 1 and 2 were measured under the following conditions using V-730 equipment (commercially available from JASCO Inc.). The results are shown in Table 1.

Wavelength range: 200 nm to 1,100 nm; Scanning speed: 400 nm/min

TABLE 1

| | | | | Reflectance | Transmittance |
|---|---|---|---|---|---|
| Items | L* | a* | b* | (%) | (%) |
| Example 1 | 26.0 | 3.23 | 12.3 | 5.54 | 2.66 |
| Comparative | 96.2 | 0.02 | −0.20 | 9.58 | 87.1 |
| Example 1 | | | | | |
| Comparative | 100 | 0.00 | −0.01 | 7.11 | 93.4 |
| Example 2 | | | | | |

Referring to Table 1, in the case of Example 1, it can be seen that the L* value of the CIE L*a*b* color space and the transmittance were significantly lower than those of Comparative Examples 1 and 2 due to an effect of defective carbon. As shown in FIG. 2, it can be seen that the sample of the sintered body (E1) of Example 1 appears relatively blacker.

### Experimental Example: Measure of Plasma Corrosion Resistance

The plasma corrosion resistances of the sintered body of Example 1 and the quartz glasses of Comparative Examples 1 and 2 were measured under the following conditions. The results are shown in Table 2.

Chamber pressure: 100 mTorr; Plasma power: 800 W: Exposure time: 300 minutes; CF₄ gas flow rate: 50 sccm; Ar gas flow rate: 100 sccm; and O₂ gas flow rate: 20 sccm

TABLE 2

| | | Comparative | Comparative |
|---|---|---|---|
| Items | Example 1 | Example 1 | Example 2 |
| Thickness before etching (mm) | 1.9994 | 1.9896 | 1.9878 |
| Thickness after etching (mm) | 1.9734 | 1.958 | 1.96 |
| Etched thickness (mm) | 0.026 | 0.0316 | 0.0278 |
| Thickness decrease rate (%) | 1.30039 | 1.58826 | 1.39853 |
| Weight before etching (g) | 0.43747 | 0.43763 | 0.43667 |
| Weight after etching (g) | 0.43153 | 0.4307 | 0.43043 |
| Weight decrease rate (%) | 0.00594 | 0.00693 | 0.00624 |

Referring to Table 2, it was confirmed that the sintered body of Example 1 had superior plasma etching resistance due to a lower thickness decrease rate and a lower weight decrease rate, compared to the quartz glasses of Comparative Examples 1 and 2.

### Experimental Example: XPS Analysis Before and After Plasma Etching

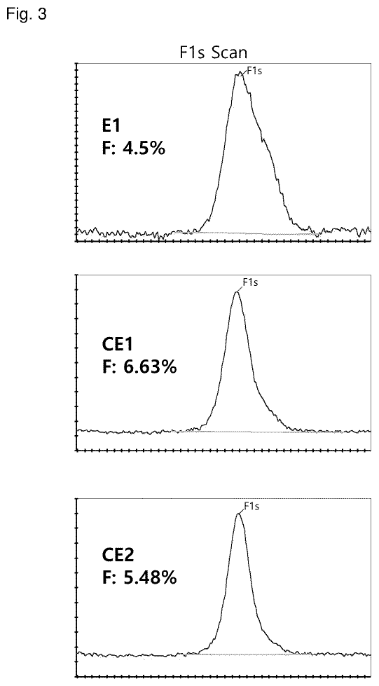

Before and after the measurement of the plasma corrosion resistance of the sintered body of Example 1 and the quartz glasses of Comparative Examples 1 and 2, X-ray photoelectron spectroscopy (XPS) was performed using Sigma Probe equipment (commercially available from Thermo VG Scientific). The results are shown in FIG. 3 and Table 3.

TABLE 3

| | | | | |
|---|---|---|---|---|
| Items | O1s | Si2p | C1s | F1s |

Before etching

| | | | | |
|---|---|---|---|---|
| Peak binding energy of Example 1 | 532.61 | 103.37 | 284.78 | — |
| (eV) | | | | |
| Peak binding energy of | 532.77 | 103.5 | 284.82 | — |
| Comparative Example 1 (eV) | | | | |
| Peak binding energy of | 532.77 | 103.51 | 284.82 | — |
| Comparative Example 2 (eV) | | | | |
| Peak area ratio of Example 1 (%) | 46.63 | 22.86 | 28.43 | |
| Peak area ratio of Comparative | 46.33 | 23.2 | 29.5 | — |
| Example 1 (%) | | | | |
| Peak area ratio of Comparative | 46.66 | 23.15 | 29.11 | — |
| Example 2 (%) | | | | |

After etching

| | | | | |
|---|---|---|---|---|
| Peak binding energy of Example 1 | 532.92 | 103.57 | 284.81 | 686.89 |
| (eV) | | | | |
| Peak binding energy of | 532.94 | 103.65 | 284.82 | 687.19 |
| Comparative Example 1 (eV) | | | | |
| Peak binding energy of | 532.79 | 103.49 | 284.69 | 687.05 |
| Comparative Example 2 (eV) | | | | |
| Peak area ratio of Example 1 (%) | 51.84 | 26.33 | 17.32 | 4.5 |
| Peak area ratio of Comparative | 53.32 | 28 | 12.04 | 6.63 |
| Example 1 (%) | | | | |
| Peak area ratio of Comparative | 56.31 | 29.1 | 9.11 | 5.48 |
| Example 2 (%) | | | | |

Referring to FIG. 3 and Table 3, it can be seen that the sintered body of Example 1 had a relatively small carbon change before and after plasma etching, compared to the quartz glasses of Comparative Examples 1 and 2, and a small amount of F was also produced by reaction with the etching gas.

### Experimental Example: XRF and ICP-MS Analysis

The sintered body samples of Example 1 and the quartz glasses of Comparative Examples 1 and 2 were analyzed by X-ray fluorescence spectrometry (XRF) using ZSX Primus equipment (commercially available from Rigaku Corp.), and a content of the impurities was measured by inductively coupled plasma-mass-spectrometry (ICP-MS) using HR-ICP/MS equipment (commercially available from Thermo Fisher Scientific Inc.). The results are shown in Tables 4 and 5.

TABLE 4

| | C | O | Si |
|---|---|---|---|
| Items | (% by weight) | (% by weight) | (% by weight) |
| Example 1 | 0.7928 | 53.7649 | 45.4373 |
| Comparative | 0.7178 | 53.1511 | 46.1312 |
| Example 1 | | | |
| Comparative | 0.8589 | 53.4491 | 45.6920 |
| Example 2 | | | |

Referring to Table 4, it can be seen that all of the sintered body of Example 1 and the quartz glasses of Comparative Examples 1 and 2 had similar carbon, oxygen, and silicon contents, as determined by XRF analysis.

TABLE 5

| | | Comparative | Comparative |
|---|---|---|---|
| Items | Example 1 | Example 1 | Example 2 |
| Li | 0.76 | 23.96 | 0.76 |
| Be | 0.03 | 0.56 | 0.06 |
| Na | 1992.26 | 2382.95 | 7.01 |
| Mg | 1375.96 | 97.8 | 0.83 |
| Al | 4491.11 | 8521.34 | 142.97 |
| K | 1377.87 | 373.81 | 6.96 |
| Ca | 7748.53 | 809.3 | 3.63 |
| Ti | 126.75 | 1476.1 | 20.79 |
| Cr | 498.82 | 3.95 | 0.34 |
| Mn | 53.3 | 18.41 | 0.12 |
| Fe | 2664.09 | 430.8 | 8.51 |
| Ni | 196.29 | 0.41 | 0.06 |
| Co | 3.31 | 0.07 | 0.02 |
| Cu | 1.8 | 1.38 | 5.17 |
| Zn | 34.64 | 2.37 | 0.37 |
| Ga | 2.02 | 0.37 | 0.02 |
| Ge | 8.79 | 608.86 | 0.03 |
| Ba | 738.91 | 13.84 | 0.2 |
| W | 31.09 | 0.37 | 0.03 |
| Pb | 10.66 | 5.64 | 0.01 |
| Total | 21356.99 | 14772.29 | 197.89 |

Units: ppb

Referring to Table 5, it can be seen from the results according to ICP-MS that the sintered body of Example 1 had higher magnesium, potassium, calcium, chromium, iron, nickel, and barium contents compared to those of Comparative Examples 1 and 2.

The quartz glass-based sintered body according to the present disclosure may have improved plasma corrosion resistance compared to conventional synthetic quartz glass.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A sintered body comprising silicon oxide and carbon,
wherein the sintered body has a D band peak at a wave number of 1,311 cm⁻¹ to 1,371 cm⁻¹ and a G band peak at a wave number of 1,572 cm⁻¹ to 1,632 cm⁻¹ in a Raman spectrum, and
wherein the D band peak or the G band peak have a higher intensity than a fifth peak present at a wave number of 1,027 cm⁻¹ to 1,087 cm⁻¹ in the Raman spectrum.

2. The sintered body of claim 1, wherein the D band peak or the G band peak has an intensity 1.5 times or more and 5 times or less higher than the fifth peak.

3. The sintered body of claim 1, wherein the D band peak or the G band peak has a higher intensity than a fourth peak present at a wave number of 762 cm⁻¹ to 822 cm⁻¹.

4. The sintered body of claim 1, wherein an average intensity at a wave number of 1,212 cm⁻¹ to 1,262 cm⁻¹ in the Raman spectrum is higher than the intensity of the fifth peak.

5. The sintered body of claim 1, wherein an intensity ratio I_{d}/I_{g} of the D band peak and the G band peak is greater than or equal to 0.9 and less than or equal to 1.5.

6. The sintered body of claim 1, wherein the sintered body has a compressive strength of 380 MPa or more and 580 Mpa or less.

7. The sintered body of claim 1, wherein a content of the carbon is greater than or equal to 0.01% by weight and less than or equal to 1.5% by weight based on a total weight of the sintered body.

8. The sintered body of claim 1, wherein a content of silicon is greater than or equal to 40% by weight and less than or equal to 49% by weight based on a total weight of the sintered body and a content of oxygen is greater than or equal to 47% by weight and less than or equal to 56% by weight based on the total weight of the sintered body.

9. The sintered body of claim 1, wherein the sintered body comprises a metal impurity selected from the group consisting of magnesium, potassium, calcium, chromium, iron, nickel, and barium.

10. The sintered body of claim 9, wherein a content of the magnesium is greater than or equal to 100 ppb and less than or equal to 2,500 ppb based on a total weight of the sintered body; a content of the potassium is greater than or equal to 500 ppb and less than or equal to 2,500 ppb based on the total weight of the sintered body; a content of the calcium is greater than or equal to 1,000 ppb and less than or equal to 1,200 ppb based on the total weight of the sintered body; a content of the chromium is greater than or equal to 100 ppb and less than or equal to 1,000 ppb based on the total weight of the sintered body; a content of the iron is greater than or equal to 800 ppb and less than or equal to 5000 ppb based on the total weight of the sintered body; a content of the nickel is greater than or equal to 50 ppb and less than or equal to 800 ppb based on the total weight of the sintered body; and a content of the barium is greater than or equal to 100 ppb and less than or equal to 2000 ppb based on the total weight of the sintered body.

11. The sintered body of claim 1, wherein a thickness decrease rate of the sintered body after etching under the following plasma etching conditions in a chamber is less than or equal to 1.38% compared to a thickness decrease rate of the sintered body before etching: a chamber pressure of 100 mTorr, a plasma power of 800 W, an exposure time of 300 minutes, a CF₄ flow rate of 50 sccm, an Ar flow rate of 100 sccm, and an O₂ flow rate of 20 sccm.

12. The sintered body of claim 1, wherein an L* value of a CIE L*a*b* color space according to ASTM E1164 of the sintered body is greater than or equal to 0 and less than or equal to 85.

13. The sintered body of claim 1, wherein a light transmittance of the sintered body at a wavelength of 550 nm is 0.5% or more and 30% or less.

14. A plasma etching-resistant part comprising the sintered body of claim 1 as a coating layer on a surface of the plasma etching-resistant part.

15. The plasma etching-resistant part of claim 14, wherein a thickness of the coating layer is greater than or equal to 50 mm and less than or equal to 1,000 mm.

16. The plasma etching-resistant part of claim 14, wherein the plasma etching-resistant part is a focus ring in a plasma etching device.

17. A method of manufacturing a sintered body comprising:
forming a raw material composition in a form of granules; and
molding, carbonizing and sintering the raw material composition,
wherein the raw material composition comprises silicon oxide, a carbonizing resin, and an auxiliary additive.

18. The method of claim 17, wherein a content of the carbonizing resin is greater than or equal to 0.1% by weight and less than or equal to 8% by weight based on a total weight of the raw material composition.

19. The method of claim 17, wherein the forming of the raw material composition is performed by spray drying the raw material composition.

20. The method of claim 17, wherein the auxiliary additive comprises one selected from the group consisting of a polyacrylic acid-based resin, a polycarboxylic acid-based resin, a C₁₀-C₄₀ alkane, a fatty acid amide, and a combination thereof.
